(19) United States
(12) Patent Application Publication
(10) Pub. No.: US 2012/0299784 A1
(43) Pub. Date: Nov. 29, 2012

(54) MOBILE WIRELESS COMMUNICATIONS DEVICE INCLUDING AN ANTENNA HAVING A SHORTING PLATE

(75) Inventor: Mina Ayatollahi, Waterloo (CA)

(73) Assignees: Ontario, Canada), Waterloo (CA); Research In Motion Limited (a corporation organized under the laws of the Province of

(21) Appl. No.: 13/114,532

(22) Filed: May 24, 2011

(51) Int. Cl. H01Q 1/24; H05K 13/00; H01P 11/00

(52) U.S. Cl. 343/702; 29/601

(57) ABSTRACT

A mobile wireless communications device may include a housing, a substrate carried by the housing, and a ground plane adjacent the substrate. The mobile wireless communications device may also include wireless communications circuitry, and first and second antennas coupled to the wireless communications circuitry. The first antenna may include a base electrical conductor spaced above the substrate, and at least one feed leg extending downwardly from the base electrical conductor to the substrate. The first antenna may also include an electrically conductive shorting plate extending downwardly from the base electrical conductor from a portion thereof adjacent the second antenna and coupled to the ground plane.

### TECHNICAL FIELD

The present disclosure generally relates to the field of wireless communications systems, and, more particularly, to mobile wireless communications devices and related methods.

### BACKGROUND

Mobile wireless communications systems continue to grow in popularity and have become an integral part of both personal and business communications. For example, cellular telephones allow users to place and receive voice calls almost anywhere they travel. Moreover, as cellular telephone technology has increased, so too has the functionality of cellular devices and the different types of devices available to users. For example, many cellular devices now incorporate personal digital assistant (PDA) features such as calendars, address books, task lists, etc. Moreover, such multi-function devices may also allow users to wirelessly send and receive electronic mail (email) messages and access the Internet via a cellular network and/or a wireless local area network (WLAN), for example.

Even so, as the functionality of cellular communications devices continues to increase, so too does the demand for smaller devices which are easier and more convenient for users to carry. One challenge this poses for cellular device manufacturers is designing antennas that provide desired operating characteristics within the relatively limited amount of space available for antennas.

### BRIEF DESCRIPTION OF THE DRAWINGS

FIG. 1 is a top plan view of a mobile wireless communications device including a first and second antenna in accordance with one example embodiment.

FIG. 2 is a schematic block diagram of the device of FIG. 1.

FIG. 3 is perspective view of a portion of a mobile wireless communications device including the first and second antennas of the device of FIG. 1.

FIG. 4 is a graph of simulated S-parameters for different first and second antennas including the first and second antennas of FIG. 3.

FIGS. 5a-5c are graphs of simulated gain for the first and second antennas of FIG. 3.

FIG. 6 is a schematic block diagram illustrating in more detail components that may be included in the mobile wireless communications device of FIG. 1.

### DETAILED DESCRIPTION

The present description is made with reference to the accompanying drawings, in which various embodiments are shown. However, many different embodiments may be used, and thus the description should not be construed as limited to the embodiments set forth herein. Rather, these embodiments are provided so that this disclosure will be thorough and complete. Like numbers refer to like elements throughout.

In accordance with one exemplary aspect, a mobile wireless communications device may include a housing, a substrate carried by the housing, and a ground plane, which may include a conductive material, adjacent the substrate. The mobile wireless communications device may also include wireless communications circuitry, and first and second antennas coupled to the wireless communications circuitry, for example. The first antenna may include a base electrical conductor spaced above the substrate, and at least one feed leg extending downwardly from the base electrical conductor to the substrate and coupled to the wireless communications circuitry. The first antenna may also include an electrically conductive shorting plate extending downwardly from the base electrical conductor from a portion thereof adjacent the second antenna and coupled to the ground plane, for example.

The first antenna may further include an electrically conductive lip extending downwardly from the base electrical conductor on a side edge thereof opposite the at least one feed leg, toward the substrate and spaced therefrom. The electrically conductive lip may extend downwardly from the side edge along an entire length thereof, for example. The electrically conductive shorting plate may extend downwardly along less than an entire length of the portion of the base electrical conductor, for example.

The second antenna may include a base electrical conductor spaced above the substrate, and at least one feed leg extending downwardly from the base conductor to the substrate. The second antenna may also include an electrically conductive shorting plate extending downwardly from the base electrical conductor from a portion thereof adjacent the first antenna and coupled to the ground plane, for example.

The second antenna may further include an electrically conductive lip extending downwardly from the base electrical conductor on a side edge thereof opposite the at least one feed leg, toward the substrate and spaced therefrom, for example. The electrically conductive lip of the second antenna may extend downwardly from the side edge along an entire length thereof. The electrically conductive shorting plate of the second antenna may extend downwardly along less than an entire length of the portion of the base electrical conductor, for example.

The at least one feed leg may include a first feed leg extending downwardly from the base electrical conductor to the substrate. The at least one feed leg may also include a second feed leg extending downwardly from the base electrical conductor and coupled to the ground plane, for example.

A method aspect is directed to a method of making a mobile wireless communications device. The mobile device may include a housing, a substrate carried by the housing, a ground plane adjacent the substrate, and wireless communications circuitry. The method may include forming first and second antennas on the substrate and coupled to the wireless communications circuitry, for example. Forming the first antenna may include a base electrical conductor spaced above the substrate, and forming at least one feed leg extending downwardly from the base electrical conductor to the substrate. Forming the first antenna may also include forming an electrically conductive shorting plate extending downwardly from the base electrical conductor from a portion thereof adjacent the second antenna and coupled to the ground plane.

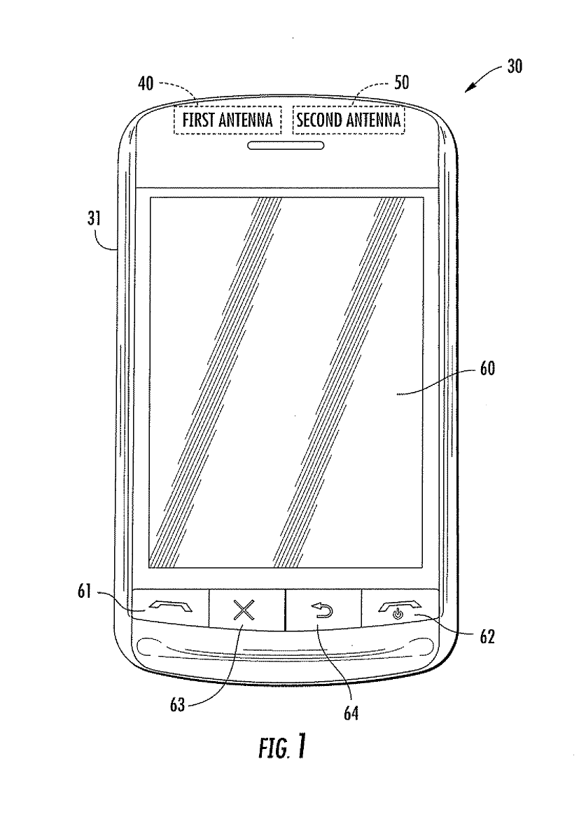

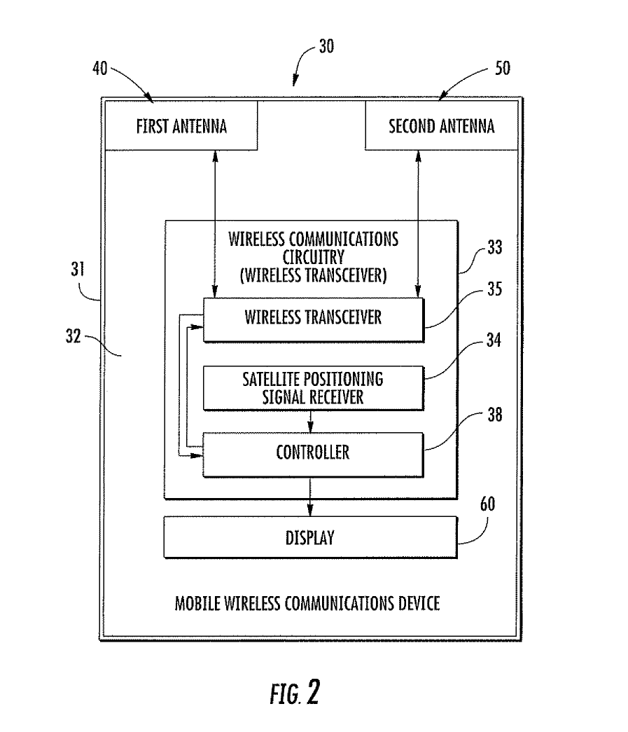

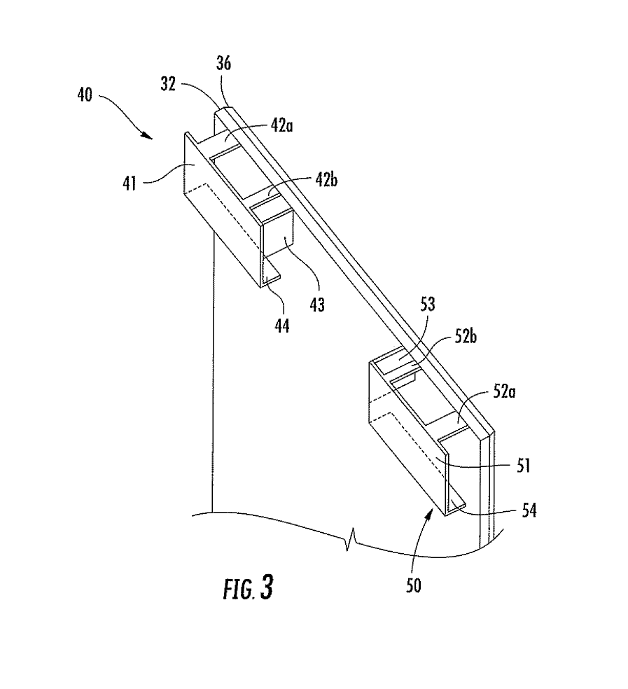

Referring initially to FIGS. 1-3, a mobile wireless communications device 30 illustratively includes a housing 31 and a substrate 32, for example, a printed circuit board (PCB) carried by the housing. The housing 31 has an upper portion and a lower portion. The substrate 32 may be a rigid PCB, or may be a flexible substrate or PCB, for example. In some embodiments wherein a PCB is used, the PCB may be replaced by or used in conjunction with a metal chassis or other substrate, as will be appreciated by those skilled in the art. A ground plane 36 is illustratively adjacent the substrate 32. A conductive layer carried the substrate 32 may define the ground plane 36 (FIG. 2).

Wireless communications circuitry 33 is carried by the housing 31. The wireless communications circuitry 33 may include, for example, a wireless transceiver 35. The wireless communications circuitry may also include, in some embodiments, a satellite positioning signal receiver 34. The satellite positioning signal receiver 34 may be a Global Positioning System (GPS) satellite receiver, for example. Of course, the mobile wireless communications device 30 may not include a satellite positioning receiver, or may include additional receivers and/or transmitters, for example, near-field communications (NFC) receivers and/or transmitters and wireless local area network receivers (e.g. 802.xx, WiFi). The satellite positioning receiver 34 or other or additional receivers and/or transmitters may not be part of the wireless communications circuitry 33, as will be appreciated by those skilled in the art.

The exemplary device 30 further illustratively includes a display 60 and a plurality of control keys including an “off hook” (i.e., initiate phone call) key 61, an “on hook” (i.e., discontinue phone call) key 62, a menu key 63, and a return or escape key 64. Operation of the various device components and input keys, etc., will be described further below with reference to FIG. 6.

The device 30 further illustratively includes first and second antennas 40, 50 carried adjacent the upper portion of the housing 31 and positioned along a perimeter of the housing. In some embodiments, one or both of the first and second antennas 40, 50 may be carried adjacent another portion of the housing 31, and may not be positioned along the perimeter of the housing. The first and second antennas 40, 50 are advantageously each a planar inverted F-antenna (PIFA) that may be tuned to different frequency bands, for example. The first and second antennas 40, 50 are particularly advantageous for use in a multiple-input and multiple-output (MIMO) antenna array to improve communication performance, for example. As will be appreciated by those skilled in the art, using multiple antennas, i.e. MIMO technology, may provide increased data throughput and link range with reduced additional bandwidth or transmit power, and may also provide increased spectral efficiency and link reliability or diversity.

The first antenna 40 illustratively includes a base electrical conductor 41 spaced above the substrate 32. The base electrical conductor 41 may be flat, or contoured to fit within the housing 31, for example. The first antenna 40 also includes a first feed leg 42a extending downwardly from the base electrical conductor 41 to the substrate 32 and coupled to the wireless communication circuitry 33. The first antenna 40 also includes a second feed leg 42b, or ground leg, extending downwardly from the base electrical conductor 41 and coupled to the ground plane 36. While the first and second feed legs 42a, 42b are illustratively positioned along a first edge of the base electrical conductor 41 adjacent or facing the uppermost portion of the housing 31, the first and second feed legs may be positioned to extend downwardly from other areas of the base electrical conductor to increase antenna performance. The first antenna 40 may include additional feed legs that may be coupled to the wireless communications circuitry 33.

The first antenna 40 also includes an electrically conductive shorting plate 43 extending downwardly from the base electrical conductor 41 from a portion thereof adjacent the second antenna 50. In other words, the electrically conductive shorting plate 43 faces the second antenna 50. The electrically conductive shorting plate 43 is also coupled to the ground plane 36. The electrically conductive shorting plate 43 illustratively extends downwardly along less than an entire length of the portion of the base electrical conductor 41. In some embodiments, the electrically conductive shorting plate 43 may extend along the entire length of the portion of the base electrical conductor 41.

The first antenna 40 also includes an electrically conductive lip 44 extending downwardly from the base electrical conductor 41 on a second edge thereof opposite the first and second feed legs 42a, 42b. The electrically conductive lip 44 extends downwardly from the base electrical conductor 41 toward the substrate 32 and is spaced from the substrate. Illustratively, the electrically conductive lip 44 extends downwardly from the second edge of the base electrical conductor 41 along an entire length thereof. Of course, the electrically conductive lip 44 may extend less than entire length of the second edge of the base electrical conductor 41.

The second antenna 50 illustratively includes a mirror image arrangement of the same structural elements as the first antenna 40. More particularly, the second antenna 50 includes a base electrical conductor 51 spaced above the substrate 32, first and second feed legs 52a, 52b extending downwardly from the base conductor to the substrate, and an electrically conductive shorting plate 53 extending downwardly from the base electrical conductor from a portion thereof adjacent the first antenna 40 and coupled to the ground plane 36. The second antenna 50 also includes an electrically conductive lip 54 extending downwardly from the base electrical conductor 51 on a side edge thereof opposite the first and second feed legs 52a, 52b, toward the substrate 32 and spaced therefrom.

Indeed, it may be preferred that elements of second antenna 50 be configured the same as the first antenna 40, for example, so that the second antenna is a mirror image of the first antenna, as illustrated. Of course, the elements of the second antenna 50 may be configured differently from the respective elements of the first antenna 40 and/or may include more or less elements. For example, the electrically conductive lip 54 of the second antenna may not extend downwardly from the side edge along an entire length thereof, and/or the electrically conductive shorting plate 53 of the second antenna may not extend downwardly along less than an entire length of the portion of the base electrical conductor 51, vis-à-vis the first antenna 40. The elements of the first and second antennas 40, 50 may be configured in other configurations, as will be appreciated by those skilled in the art.

It will be appreciated by those skilled in the art that PIFAs may be used in mobile devices because of their increased bandwidth and increased efficiency. However, using multiple antennas in a mobile device may be increasingly difficult as the distance between the antennas is relatively small, which may result in increased mutual coupling between the antennas. While the isolation between the antennas may be increased, for example, by forming slots on the ground plane between the antenna elements and electromagnetic band gap (EBG) ground planes, these approaches generally occupy increased space on the limited substrate or PCB area, which may be reserved for other components. The first and second antennas 40, 50 advantageously reduce the mutual coupling between therebetween, especially in a relatively small or compact space, as in the housing 31, for example.

The electrically conductive shorting plates 43, 53 extending downwardly from the base electrical conductor 41, 51 from the portion thereof adjacent the other antenna 50, 40, respectively, advantageously reduce the mutual coupling therebetween. In particular, while the electrically conductive shorting plates 43, 53 may extend less than an entire length of the portion of the respective base electrical conductors 41, 51, it is generally desirable that the electrically conductive shorting plates 43, 53 do not extend less than a quarter of the length of the respective base electrical conductors 41, 51. Indeed, as will be appreciated by those skilled in the art, the electrically conductive shorting plates 43, 53 extending less than a quarter of the length may not provide adequate reduction of the mutual coupling.

Additionally, each electrically conductive shorting plate 43, 53, also increases the resonance frequency of each antenna 40, 50. More particularly, each antenna 40, 50 is extended vertically above the ground plane 36 from its edge. In particular, by adding approximately 2 millimeters to the electrically conductive shorting plate 43, 53, the resonance frequency may be changed from 5 GHz to 5.5 GHz, for example.

Additionally, as will be appreciated by those skilled in the art, altering the shape, connecting, and/or disconnecting any of the electrically conductive shorting plates 43, 53 and the electrically conductive lips 44, 54, changes the resonance frequencies of the first and second antennas 40, 50, respectively. In particular, the electrically conductive lips 44, 54 adjust or account for any change in the resonance frequency that may be caused by the shorting plates 43, 53. This way, the resonance frequencies of the first and second antennas 40, 50 may be “tuned” to operate in different frequency bands, for example.

The wireless communications circuitry 33 may also include a controller 38 or processor. The controller 38 may cooperate with the other components, for example, the first and second antennas 40, 50, the satellite positioning signal receiver 34, and the wireless transceiver 33 to coordinate and control operations of the mobile wireless communications device 30. Operations may include mobile voice and data operations, including email and Internet data.

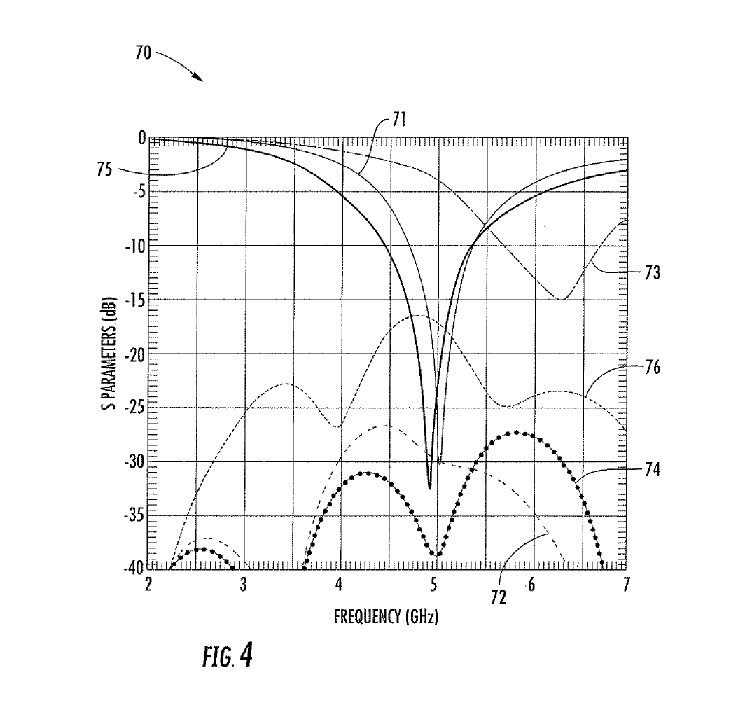

Referring now to the graph 70 in FIG. 4, the simulated S parameter for the antennas 40, 50 is graphed and indicated by lines 71 and 72, respectively. Lines 73 and 74 indicate simulated results for first and second antennas that do not include the electrically conductive lip 44, 54. Moreover, lines 75 and 76 indicate simulated results for first and second antennas that do not include both the electrically conductive shorting plate 43, 53 and the electrically conductive lip 44, 54. As shown in the graph of FIG. 4, by adding the shorting plates 43, 53, the mutual coupling between the antennas 40, 50 has been reduced by at least −10 dB.

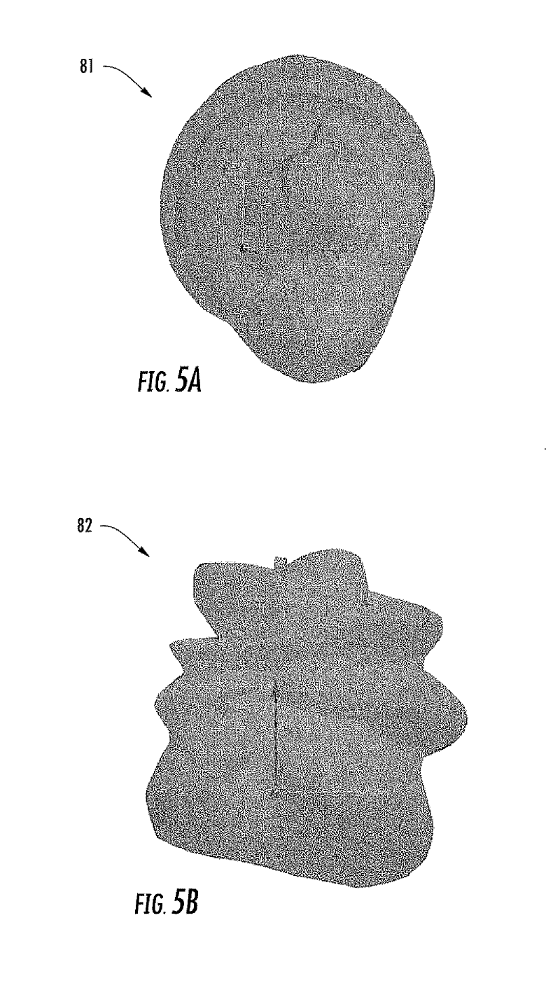

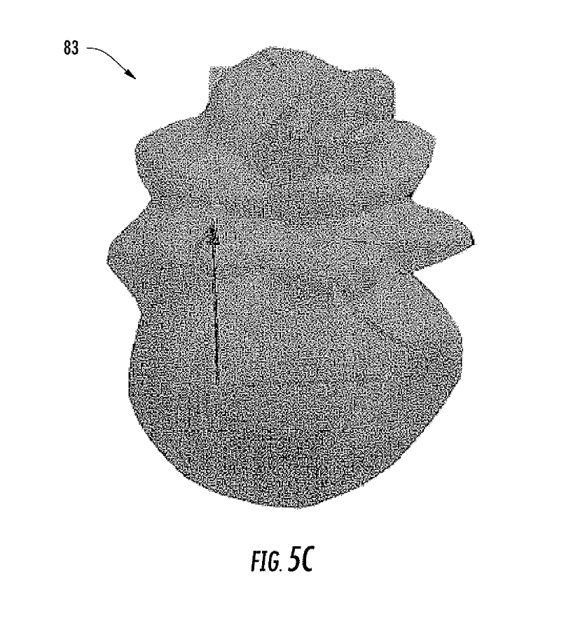

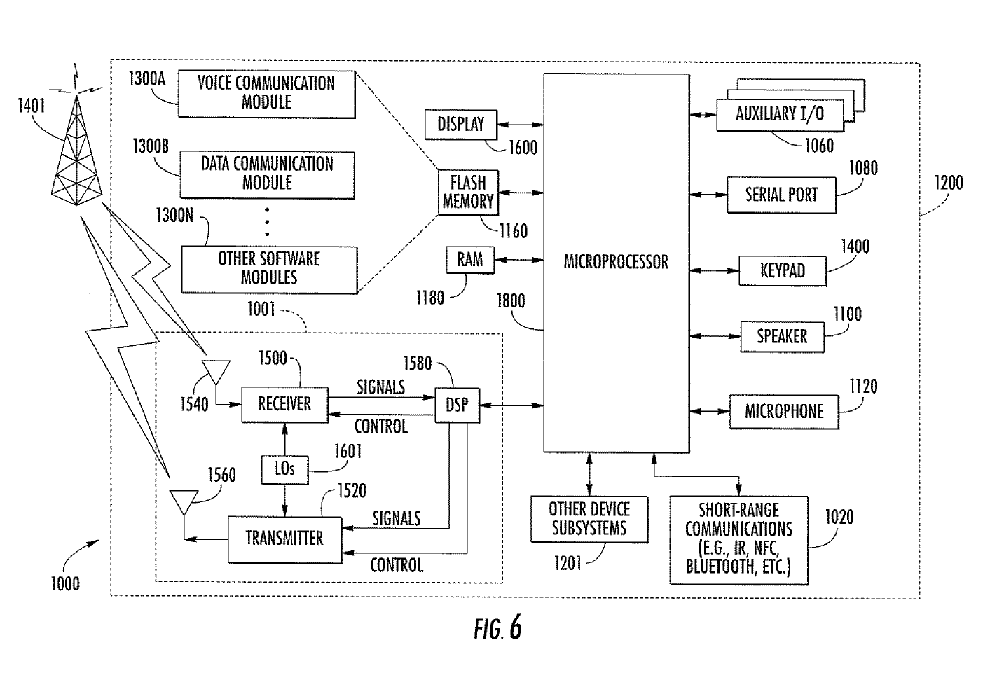

Referring now to the graphs 81, 82, and 83, in FIGS. 5a-5c, respectively, the gains along three-axes (X, Y, Z) are illustrated. The Z axis is along the length of the substrate 32 with +Z pointing to the bottom of substrate (opposite the edge which the antennas 40, 50 are positioned), X is along the width and Y is along the depth or thickness. The graph 81 in FIG. 5a illustrates the simulated gain taken along the XY axes for the antennas 40, 50. The graph 82 in FIG. 5b illustrates the simulated gain taken along the YZ axes for the antennas 40, 50. The graph 83 in FIG. 5c illustrates the simulated gain taken along the XZ axes for the antennas 40, 50. The gain is simulated to be 7 dB at 5.6 GHz.

A method aspect is directed to a method of making a mobile wireless communications device 30. The mobile device 30 includes a housing 31, a substrate 32 carried by the housing, a ground plane 36 adjacent the substrate, and wireless communications circuitry 33. The method includes forming first and second antennas 40, 50 on the substrate and coupled to the wireless communications circuitry 33, for example. Forming the first antenna 40 includes forming a base electrical conductor 41 spaced above the substrate 32, and forming at least one feed leg 42a extending downwardly from the base electrical conductor to the substrate. Forming the first antenna 40 may also include forming an electrically conductive shorting plate 43 extending downwardly from the base electrical conductor 41 from a portion thereof adjacent the second antenna 50 and coupled to the ground plane 36.

Example components of a mobile wireless communications device 1000 that may be used in accordance with the above-described embodiments are further described below with reference to FIG. 6. The device 1000 illustratively includes a housing 1200, a keyboard or keypad 1400 and an output device 1600. The output device shown is a display 1600, which may comprise a full graphic LCD. Other types of output devices may alternatively be utilized. A processing device 1800 is contained within the housing 1200 and is coupled between the keypad 1400 and the display 1600. The processing device 1800 controls the operation of the display 1600, as well as the overall operation of the mobile device 1000, in response to actuation of keys on the keypad 1400.

The housing 1200 may be elongated vertically, or may take on other sizes and shapes (including clamshell housing structures). The keypad may include a mode selection key, or other hardware or software for switching between text entry and telephony entry.

In addition to the processing device 1800, other parts of the mobile device 1000 are shown schematically in FIG. 6. These include a communications subsystem 1001; a short-range communications subsystem 1020; the keypad 1400 and the display 1600, along with other input/output devices 1060, 1080, 1100 and 1120; as well as memory devices 1160, 1180 and various other device subsystems 1201. The mobile device 1000 may comprise a two-way RF communications device having data and, optionally, voice communications capabilities. In addition, the mobile device 1000 may have the capability to communicate with other computer systems via the Internet.

Operating system software executed by the processing device 1800 is stored in a persistent store, such as the flash memory 1160, but may be stored in other types of memory devices, such as a read only memory (ROM) or similar storage element. In addition, system software, specific device applications, or parts thereof, may be temporarily loaded into a volatile store, such as the random access memory (RAM) 1180. Communications signals received by the mobile device may also be stored in the RAM 1180.

The processing device 1800, in addition to its operating system functions, enables execution of software applications 1300A-1300N on the device 1000. A predetermined set of applications that control basic device operations, such as data and voice communications 1300A and 1300E, may be installed on the device 1000 during manufacture. In addition, a personal information manager (PIM) application may be installed during manufacture. The PIM may be capable of organizing and managing data items, such as e-mail, calendar events, voice mails, appointments, and task items. The PIM application may also be capable of sending and receiving data items via a wireless network 1401. The PIM data items may be seamlessly integrated, synchronized and updated via the wireless network 1401 with corresponding data items stored or associated with a host computer system.

Communication functions, including data and voice communications, are performed through the communications subsystem 1001, and possibly through the short-range communications subsystem. The communications subsystem 1001 includes a receiver 1500, a transmitter 1520, and one or more antennas 1540 and 1560. In addition, the communications subsystem 1001 also includes a processing module, such as a digital signal processor (DSP) 1580, and local oscillators (LOs) 1601. The specific design and implementation of the communications subsystem 1001 is dependent upon the communications network in which the mobile device 1000 is intended to operate. For example, a mobile device 1000 may include a communications subsystem 1001 designed to operate with the Mobitex™, Data TAC™ or General Packet Radio Service (GPRS) mobile data communications networks, and also designed to operate with any of a variety of voice communications networks, such as AMPS, TDMA, CDMA, WCDMA, PCS, GSM, EDGE, etc. Other types of data and voice networks, both separate and integrated, may also be utilized with the mobile device 1000. The mobile device 1000 may also be compliant with other communications standards such as 3GSM, 3GPP, UMTS, 4G, etc.

Network access requirements vary depending upon the type of communication system. For example, in the Mobitex and DataTAC networks, mobile devices are registered on the network using a unique personal identification number, or PIN associated with each device. In GPRS networks, however, network access is associated with a subscriber or user of a device. A GPRS device therefore typically involves use of a subscriber identity module, commonly referred to as a SIM card, in order to operate on a GPRS network.

When required network registration or activation procedures have been completed, the mobile device 1000 may send and receive communications signals over the communication network 1401. Signals received from the communications network 1401 by the antenna 1540 are routed to the receiver 1500, which provides for signal amplification, frequency down conversion, filtering, channel selection, etc., and may also provide analog to digital conversion. Analog-to-digital conversion of the received signal allows the DSP 1580 to perform more complex communications functions, such as demodulation and decoding. In a similar manner, signals to be transmitted to the network 1401 are processed (e.g. modulated and encoded) by the DSP 1580 and are then provided to the transmitter 1520 for digital to analog conversion, frequency up conversion, filtering, amplification and transmission to the communication network 1401 (or networks) via the antenna 1560.

In addition to processing communications signals, the DSP 1580 provides for control of the receiver 1500 and the transmitter 1520. For example, gains applied to communications signals in the receiver 1500 and transmitter 1520 may be adaptively controlled through automatic gain control algorithms implemented in the DSP 1580.

In a data communications mode, a received signal, such as a text message or web page download, is processed by the communications subsystem 1001 and is input to the processing device 1800. The received signal is then further processed by the processing device 1800 for an output to the display 1600, or alternatively to some other auxiliary I/O device 1060. A device may also be used to compose data items, such as e-mail messages, using the keypad 1400 and/or some other auxiliary I/O device 1060, such as a touchpad, a rocker switch, a thumb-wheel, or some other type of input device. The composed data items may then be transmitted over the communications network 1401 via the communications subsystem 1001.

In a voice communications mode, overall operation of the device is substantially similar to the data communications mode, except that received signals are output to a speaker 1100, and signals for transmission are generated by a microphone 1120. Alternative voice or audio I/O subsystems, such as a voice message recording subsystem, may also be implemented on the device 1000. In addition, the display 1600 may also be utilized in voice communications mode, for example to display the identity of a calling party, the duration of a voice call, or other voice call related information.

The short-range communications subsystem enables communication between the mobile device 1000 and other proximate systems or devices, which need not necessarily be similar devices. For example, the short-range communications subsystem may include an infrared device and associated circuits and components, a Bluetooth™ communications module to provide for communication with similarly-enabled systems and devices, or a near field communications (NFC) sensor for communicating with a NFC device or NFC tag via NFC communications.

Many modifications and other embodiments of the invention will come to the mind of one skilled in the art having the benefit of the teachings presented in the foregoing descriptions and the associated drawings. Therefore, it is understood that the invention is not to be limited to the specific embodiments disclosed, and that modifications and embodiments are intended to be included within the scope of the appended claims.

That which is claimed is:

1. A mobile wireless communications device comprising:
a housing;
a substrate carried by said housing;
a ground plane adjacent said substrate;
wireless communications circuitry;
first and second antennas coupled to said wireless communications circuitry; and
said first antenna comprising
a base electrical conductor spaced above said substrate,
at least one feed leg extending downwardly from said base electrical conductor to said substrate, and
an electrically conductive shorting plate extending downwardly from said base electrical conductor from a portion thereof adjacent said second antenna and coupled to said ground plane.

2. The mobile wireless communications device according to claim 1, wherein said first antenna further comprises an electrically conductive lip extending downwardly from said base electrical conductor on a side edge thereof opposite said at least one feed leg, toward said substrate and spaced therefrom.

3. The mobile wireless communications device according to claim 2, wherein said electrically conductive lip extends downwardly from the side edge along an entire length thereof.

4. The mobile wireless communications device according to claim 1, wherein said electrically conductive shorting plate extends downwardly along less than an entire length of the portion of said base electrical conductor.

5. The mobile wireless communications device according to claim 1, wherein said second antenna comprises:
a base electrical conductor spaced above said substrate;
at least one feed leg extending downwardly from said base conductor to said substrate; and
an electrically conductive shorting plate extending downwardly from said base electrical conductor from a portion thereof adjacent said first antenna and coupled to said ground plane.

6. The mobile wireless communications device according to claim 5, wherein said second antenna further comprises an electrically conductive lip extending downwardly from said base electrical conductor on a side edge thereof opposite said at least one feed leg, toward said substrate and spaced therefrom.

7. The mobile wireless communications device according to claim 6, wherein said electrically conductive lip of said second antenna extends downwardly from the side edge along an entire length thereof.

8. The mobile wireless communications device according to claim 6, wherein said electrically conductive shorting plate of said second antenna extends downwardly along less than an entire length of the portion of said base electrical conductor.

9. The mobile wireless communications device according to claim 1 wherein said at least one feed leg comprises:
a first feed leg extending downwardly from said base electrical conductor to said substrate; and
a second feed leg extending downwardly from said base electrical conductor and coupled to said ground plane.

10. A mobile wireless communications device comprising:
a housing;
a substrate carried by said housing;
a ground plane adjacent said substrate;
wireless communications circuitry;
first and second antennas coupled to said wireless communications circuitry; and
said first antenna comprising
a base electrical conductor spaced above said substrate,
a first feed leg extending downwardly from said base electrical conductor to said substrate,
a second feed leg extending downwardly from said base electrical conductor and coupled to said ground plane,
an electrically conductive shorting plate extending downwardly from said base electrical conductor from a portion thereof adjacent said second antenna and coupled to said ground plane, and
an electrically conductive lip extending downwardly from said base electrical conductor on a side edge thereof opposite said first and second feed legs, toward said substrate and spaced therefrom.

11. The mobile wireless communications device according to claim 10, wherein said electrically conductive lip extends downwardly from the side edge along an entire length thereof.

12. The mobile wireless communications device according to claim 10, wherein said electrically conductive shorting plate extends downwardly along less than an entire length of the portion of said base electrical conductor.

13. The mobile wireless communications device according to claim 10, wherein said second antenna comprises:
a base electrical conductor spaced above said substrate;
at least one feed leg extending downwardly from said base conductor to said substrate; and
an electrically conductive shorting plate extending downwardly from said base electrical conductor from a portion thereof adjacent said first antenna and coupled to said ground plane.

14. The mobile wireless communications device according to claim 13, wherein said second antenna further comprises an electrically conductive lip extending downwardly from said base electrical conductor on a side edge thereof opposite said at least one feed leg, toward said substrate and spaced therefrom.

15. The mobile wireless communications device according to claim 14, wherein said electrically conductive lip of said second antenna extends downwardly from the side edge along an entire length thereof.

16. The mobile wireless communications device according to claim 14, wherein said electrically conductive shorting plate of said second antenna extends downwardly along less than an entire length of the portion of said base electrical conductor.

17. A method of making a mobile wireless communications device comprising a housing, a substrate carried by the housing, a ground plane adjacent the substrate, and wireless communications circuitry, the method comprising:
forming first and second antennas on the substrate and coupled to the wireless communications circuitry;
forming the first antenna comprising
forming a base electrical conductor spaced above the substrate,
forming at least one feed leg extending downwardly from the base electrical conductor to the substrate, and
forming an electrically conductive shorting plate extending downwardly from the base electrical conductor from a portion thereof adjacent the second antenna and coupled to the ground plane.

18. The method according to claim 17, wherein forming the first antenna further comprises forming an electrically conductive lip extending downwardly from the base electrical conductor on a side edge thereof opposite the at least one feed leg, toward the substrate and spaced therefrom.

19. The method according to claim 18, wherein forming the electrically conductive lip comprises forming the electrically conductive lip to extend downwardly from the side edge along an entire length thereof.

20. The method according to claim 17, wherein forming electrically conductive shorting plate comprises forming the electrically conductive plate to extend downwardly along less than an entire length of the portion of the base electrical conductor.

21. The method according to claim 17, wherein forming the second antenna comprises:
forming a base electrical conductor spaced above the substrate;
forming at least one feed leg extending downwardly from the base conductor to the substrate; and
forming an electrically conductive shorting plate extending downwardly from the base electrical conductor from a portion thereof adjacent the first antenna and coupled to the ground plane.

22. The method according to claim 21, wherein forming the second antenna further comprises forming an electrically conductive lip extending downwardly from the base electrical conductor on a side edge thereof opposite the at least one feed leg, toward the substrate and spaced therefrom.

23. The method according to claim 22, wherein forming the electrically conductive lip of the second antenna comprising forming the electrically conductive lip of the second antenna to extend downwardly from the side edge along an entire length thereof.

24. The method according to claim 22, wherein forming the electrically conductive shorting plate of the second antenna comprises forming the electrically conductive shorting plate of the second antenna to extend downwardly along less than an entire length of the portion of the base electrical conductor.

25. The method according to claim 17, wherein forming the at least one feed leg comprises:
forming a first feed leg extending downwardly from the base electrical conductor to the substrate; and
forming a second feed leg extending downwardly from the base electrical conductor and to be coupled to the ground plane.
